(19) United States
(12) Patent Application Publication
(10) Pub. No.: US 2012/0107562 A1
(43) Pub. Date: May 3, 2012

(54) METHODS FOR GRAPHENE-ASSISTED FABRICATION OF MICRO-AND NANOSCALE STRUCTURES AND DEVICES FEATURING THE SAME

(75) Inventors: Kirill Bolotin, New York, NY (US); Martin Klima, Dusseldorf (DE); Horst Stormer, New York, NY (US); Philip Kim, New York, NY (US); James Hone, New York, NY (US)

(73) Assignee: The Trustees Of Columbia University In The City Of, New York, NY (US)

(21) Appl. No.: 13/149,355

(22) Filed: May 31, 2011

Related U.S. Application Data
(63) Continuation of application No. PCT/US2009/066220, filed on Dec. 1, 2009.
(60) Provisional application No. 61/186,577, filed on Jun. 12, 2009.
(60) Provisional application No. 61/118,919, filed on Dec. 1, 2008.

(51) Int. Cl. B32B 3/00; B32B 9/00; B44C 1/22; B32B 15/04; B82Y 30/00

(52) U.S. Cl. 428/156; 216/37; 428/457; 428/408; 977/734

(57) ABSTRACT

Methods for graphene-assisted fabrication of a surface on a substrate are disclosed herein. In an exemplary method, fabricating an etched surface on a substrate includes, depositing at least one layer of graphene on the surface on the substrate, patterning the deposited layer of graphene, and exposing the surface on a substrate to an acid to etch the surface on the substrate. The method can further include forming the layer of graphene from graphite. In some embodiments, the layer of graphene is formed by mechanically exfoliating the layer of graphene from the graphite. Alternatively, the layer of graphene can be formed by chemically exfoliating the graphene from the graphite, or other carbon materials, and/or utilizing vapor deposition to form the layer of graphene from the graphite, or other carbon materials.

### CROSS REFERENCE TO RELATED APPLICATIONS

This application is a continuation of International Patent Application PCT/US2009/066220, entitled “Methods For Graphene-Assisted Fabrication Of Micro- And Nanoscale Structures And Devices Featuring The Same”, filed on Dec. 1, 2009, which claims priority to U.S. Provisional Application No. 61/186,577, entitled “Graphene-Assisted Fabrication Of Nanoscale Structures”, filed on Jun. 12, 2009 and U.S. Provisional Application No. 61/118,919, entitled “Three-Terminal Device Using Mechanically-Vibrating, High Transconductance Material”, filed on Dec. 1, 2008, the disclose of each of which is incorporated by reference in its entirety herein.

### STATEMENT REGARDING FEDERALLY-SPONSORED RESEARCH

This invention was made with government support under CHE-0641523 awarded by the National Science Foundation. The government has certain rights in the invention.

### BACKGROUND

1. Field

The present application relates to methods for fabricating micro- and nanoscale structures and devices featuring such fabricated structures.

2. Background Art

Silicon dioxide (SiO₂) thermally grown on top of silicon is an important insulating material in the electronic industry. Many applications call for the patterned removal (e.g., etching) of silicon dioxide to form a variety of devices. The removal of silicon dioxide can be accomplished using a hydrofluoric acid (HF) etch that quickly dissolves the silicon dioxide, while leaving the silicon intact.

Further, many applications in the micro- and nano-electronic fields call for fabrication of devices with parts that are unsupported by the silicon substrate, e.g., suspended above the substrate. Examples of such devices would include nano-electromechanical switches, resonators and mass sensors. However, such devices are often difficult to fabricate, as material needs to be from under the device surface (e.g., the electrodes, etc.), while maintaining the structural integrity of the device.

Another challenge in small scale fabrication is the production of closed or covered cavities in a substrate surface layer such as silicon dioxide. Such cavities can serve as, for example, nanoscale reservoirs in nanofluidic devices. Accordingly, there is a need in the art for techniques for to fabricate micro- and nanoscale structures on the surfaces of substrates.

### SUMMARY

Methods for graphene-assisted fabrication of a surface on a substrate are disclosed herein. In an exemplary method, fabricating an etched surface on a substrate includes, depositing at least one layer of graphene on the surface on the substrate, patterning the deposited layer of graphene, and exposing the surface on a substrate to an acid to etch the surface on the substrate. The method can further include forming the layer of graphene from graphite. In some embodiments, the layer of graphene is formed by mechanically exfoliating the layer of graphene from the graphite. Alternatively, the layer of graphene can be formed by chemically exfoliating the graphene from the graphite, or other carbon materials, and/or utilizing vapor deposition to form the layer of graphene from the graphite, or other carbon materials.

The method can also include depositing at least one layer of metal on top of the deposited at least one layer of graphene, where the layer of metal leaves at least one portion of an edge of the layer of graphene exposed. In some embodiments, the surface on the substrate can be silicon dioxide and the acid can be hydrofluoric acid and the layer of metal can be gold. In the same or another embodiment, patterning the deposited layer of graphene includes utilizing lithography to pattern the deposited layer of graphene. Patterning the deposited layer of graphene can also include oxygen plasma etching to pattern the deposited layer of graphene.

In some exemplary embodiments exposing the surface of substrate to an acid includes acid vapor phase etching the surface and, in the same or yet other embodiments, exposing the surface to an acid includes exposing the surface to a buffered oxide etchant, which can be, e.g., diluted with water.

The disclosed subject matter further includes a graphene fabricated device including at least one layer of graphene partially suspended above a surface on a substrate. This graphene fabricated device can also include at least one layer of metal deposited on the layer of graphene. in some embodiments the layer of metal is gold.

A graphene fabricated device including at least one channel etched into a silicon substrate beneath at least one flake of graphene is also disclosed herein. In some embodiments, this graphene fabricated device can also include at least one layer of metal deposited on the at least one layer of graphene, such that the at least one layer of metal substantially covers the layer of graphene leaving at least one portion of an edge of the at least one layer of graphene exposed. The channel can also be a nanoscale channel.

A graphene fabricated device including at least one buried cavity etched into a surface on a substrate beneath at least one flake of graphene is further described herein. In some embodiments, the graphene fabricated device further includes at least one layer of metal deposited on the layer of graphene, such that the layer of metal substantially covers the layer of graphene leaving at least one portion of an edge of the layer of graphene exposed and covering the remainder of the layer of graphene, and where the exposed portion of the layer of graphene has a first width and the covered portion of the layer of graphene has a second width, the first width being less than the second width.

### BRIEF DESCRIPTION OF THE DRAWINGS

The accompanying drawings, which are incorporated and constitute part of this disclosure, illustrate some embodiments of the disclosed subject matter.

FIG. 1 illustrates a method for graphene-assisted fabrication of a substrate surface in accordance with an exemplary embodiment of the disclosed subject matter.

FIGS. 2(a)-(b) illustrate a substrate surface fabricated to illustrate the etching of the substrate surface beneath a layer of graphene in accordance with an exemplary embodiment of the disclosed subject matter.

FIG. 2(c) is a graph showing the depths of etching that occurs beneath certain layers of graphene in accordance with an exemplary embodiment of the disclosed subject matter.

FIG. 2(d) illustrates a vapor phase etching chamber used to fabricate a substrate surface in accordance with an exemplary embodiment of the disclosed subject matter.

FIGS. 3(a)-(c) illustrate a substrate surface fabricated to illustrate the impermeability of graphene in accordance with an exemplary embodiment of the disclosed subject matter.

FIGS. 3(d)-(f) illustrate a substrate surface fabricated to create a channel in the substrate surface in accordance with an exemplary embodiment of the disclosed subject matter.

FIGS. 4(a)-(b) illustrate a substrate surface fabricated to create a device suspended above the substrate in accordance with an exemplary embodiment of the disclosed subject matter.

FIGS. 5(a)-(d) illustrate a substrate surface fabricated to create a cavity in the substrate surface in accordance with an exemplary embodiment of the disclosed subject matter.

Throughout the figures and specification the same reference numerals are used to indicate similar features and/or structures.

### DETAILED DESCRIPTION

The techniques described herein are useful for etching a substrate surface with the assistance of graphene. Although the description is focused on examples utilizing a silicon dioxide substrate surface, the techniques herein can also be useful for etching other substrate surfaces, such as, e.g., quartz, polysilicon, silicon and silicon nitride

The subjected matter disclosed herein provides methods for graphene-assisted etching of substrate surfaces and devices formed using such methods. The techniques described herein make use of the recent discovery of graphene, a carbon allotrope comprising of a hexagonal lattice of sp²-hybridized carbon atoms. One property of graphene is that it allows for the etching of silicon dioxide from underneath a graphene layer placed on the silicon. Further, the etching process is accelerated along the SiO₂-graphene interface and it has also been found, as detailed below, that graphene is not permeable to most etchants, such as hydrofluoric acid, and may not be permeable to anything, even helium. Accordingly, a layer of graphene is deposited on a substrate surface to facilitate etching of that surface in areas that would otherwise be unreachable. A layer of gold can be deposited on the graphene and further on portions of the surrounding substrate surface. When the substrate surface is exposed to an etchant it will be etched where it is exposed directly to the etchant and were the etchant can enter underneath the graphene by means of an edge of graphene being exposed to the etched, but the surface will not be substantially etched beneath the edge of the gold layer exposed to the etchant.

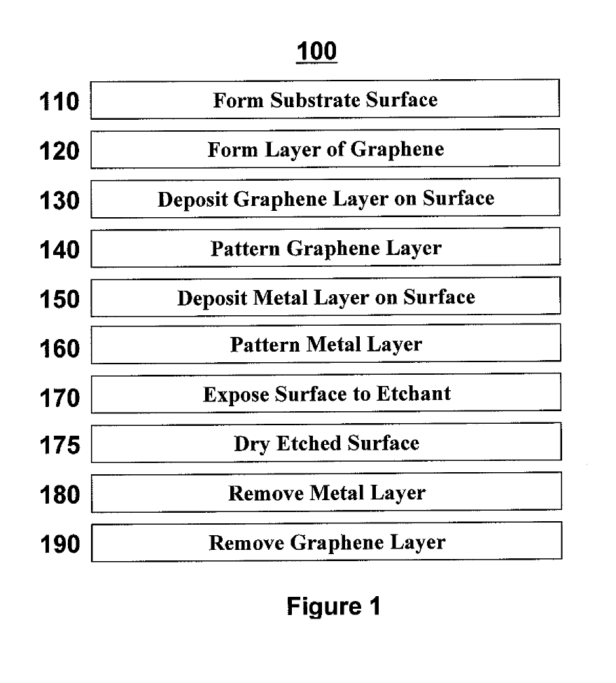

FIG. 1 illustrates a method 100 for graphene-assisted fabrication of a substrate surface. Method 100 can include forming 110 the substrate surface, or in some embodiments, the substrate surface can be provided fully formed 110. The substrate surface can be formed 110 by any suitable method known in the art, depending on the composition of the substrate surface and the substrate base upon which it is formed 110. In one exemplary embodiment, the substrate surface is composed of silicon dioxide (SiO₂) and is formed 110 on a silicon substrate base. For the example of silicon dioxide, the substrate surface can be formed 110 thermally growing the silicon dioxide on the silicon substrate base. Other techniques such as vapor deposition are also within the scope of the disclosed subject matter.

As further illustrated in FIG. 1, method 100 can further include forming 120 one or more graphene layers. The one or more graphene layers, or “flakes”, can be formed 120 by any process known it the art for forming graphene flakes, e.g., by mechanical exfoliation. The mechanical exfoliation process includes using adhesive tape, e.g., Scotch® tape, to remove graphene flakes from a stock of graphite. Other techniques for forming graphene layers, such as chemical exfoliation of graphite or vapor deposition, can also be used to form 120 the one or more graphene flakes. For example, in one embodiment utilizing a chemical exfoliation technique, the graphene can be formed 120 by chemically splitting individual sheets of graphene off of a graphite stock. Such a process can be performed in solution and then the solution can be sprayed onto the surface on the substrate, thus depositing 130 the graphene layers. The solution can then be dried leaving one or more layers of graphene deposited 130 on the substrate surface.

The graphene layers are then deposited 130 onto the substrate surface, which can be performed, in some embodiments, by laying the graphene layers on the substrate surface. In the embodiment where the graphene is formed 120 using adhesive tape, the graphene can be deposited 130 on the substrate surface by transferring the flake directly from the adhesive side of the tape to the surface, e.g., placing the adhesive side of the tape, with the flake adhered to it, directly on the substrate surface and then removing the tape from the substrate surface.

In other embodiments, the graphene can be deposited 130 on the surface on the substrate during its formation 120. For example, where the graphene layers are formed 120 by vapor deposition, such layers can be formed 120 and deposited 130 onto the substrate surface in one step. In one such embodiment utilizing a chemical vapor deposition technique, the graphene layers can formed 120 by growing the graphene on the surface of a metal, such as nickel or copper, then chemically dissolving the metal transferring 130 the graphene to the substrate surface. Transferring 130 the graphene to the substrate surface can be accomplished by adhering the grown 120 graphene to an adhesive transfer material, chemically dissolving the metal, and then depositing 130 the graphene onto the substrate surface, e.g., essentially stamping the graphene onto the surface.

The method 100 further includes patterning 140 the graphene layers into desired shapes, useful for particular applications, e.g., micro- or nano-electromechanical devices, such as micro-mirrors, accelerometers, switches, Fabir-Pero cavities, resonators, mass sensors, force sensors, etc. Patterning 140 the graphene layers can be performed either before or after the deposition 130 of the graphene layers onto the substrate surface. Further, the graphene layers can be patterned 140 utilizing any appropriate technique known in the art. For example, the graphene flakes can be patterned 140 by oxygen plasma echoing, e.g., for 6 seconds at 50 W and 200 milliTorr (mT) through a mask in an electron beam resist (PMMA 950k), to create the required shapes for a given application. The graphene layers can also be patterned 140 utilizing lithographic techniques, such as photolithography or other kinds of lithography.

In some embodiments, the method 100 further includes depositing 150 one or more layers of metal onto the substrate surface. The metal layer can be deposited 150 utilizing any appropriate technique known in the art. For example, the metal layers can deposited 150 using metal evaporation, e.g., in a vacuum using either electron beam assisted or thermally assisted, sputtering, or electrodeposition. The metal used for the metal layer will depend on the desired application and in some embodiments is gold, aluminum, copper, titanium or other metals used in semiconductor processing, as is known in the art. In other embodiments, the gold layer is deposited 150 onto of a layer of another metal, such as chromium, for adhesive purposes. The gold layer can be deposited 150 at an appropriate thickness for the particular application, e.g., 30-150 nm thick gold layer deposited 150 onto a 1-10 nm thick layer of chromium. In one embodiment a 100 nm thick gold layer was deposited 150 onto a 1 nm thick layer of chromium. In other embodiments, a 30-150 nm thick gold layer can be deposited 150 directly onto the substrate surface. Either before, during or after being deposited 150, the one or more metal layers can be patterned 160 utilizing any appropriate technique known in the art, such as electron beam or optical lithography or other lithographic techniques, to create the desired shapes for a particular application.

The method 100 further includes exposing 170 the substrate surface to an etchant capable of removing at least portions of the substrate surface. Depending on the composition of the surface, the etchant can be an acid. In an exemplary embodiment where the substrate surface is composed of silicon dioxide the etchant can be hydrofluoric acid. Other etchants can also be effective at etching 170 the substrate surface depending on the composition of the substrate surface. For example, where the substrate surface is composed of silicon, it can be etched 170 using potassium hydroxide. Exposing 170 the substrate surface to an etchant can be performed using a vapor phase technique which, in one exemplary embodiment, employs a chamber containing a heating element for receiving and controlling the temperature of the substrate surface, and a container for holding the etchant, e.g., a beaker holding hydrofluoric acid. In one embodiment, the heating element heats a silicon dioxide substrate surface to 60° C. which can produce an etching rating of about 1 nm/min.

In another exemplary embodiment, the silicon substrate surface can be exposed 170 to an etchant in liquid form to etch the silicon dioxide. The liquid can be, for example, a buffered oxide etchant such as hydrofluoric acid diluted with water at a concentration of, e.g., 50:1. The substrate surface can be exposed 170 to the liquid etchant for a period of time sufficient to remove the desired amount of the surface. In one example, a silicon dioxide substrate surface was exposed 170 to hydrofluoric acid diluted to 50:1 for 15 minutes to remove 150 nm of silicon dioxide.

After etching 170 the metal layer can be removed 180 utilizing any appropriate technique known in the art, such as etching 180 with aqua regia or a specifically formulated gold etchant (e.g., Transene TFA). Similarly, the graphene layer can also be removed 190 utilizing any appropriate technique known in the art, such as oxygen plasma etching. Further in one exemplary embodiment, after etching 170 the fabricated device can be dried 175 utilizing any technique known in the art that prevents the collapse of the suspended graphene or graphene and metal structures. For example, in an embodiment utilizing a buffered oxide etch 170 a critical point drying 175 technique utilizing ethanol can be used to reduce the probably of collapse of the suspended structure due to surface tension of the drying and/or etching liquid.

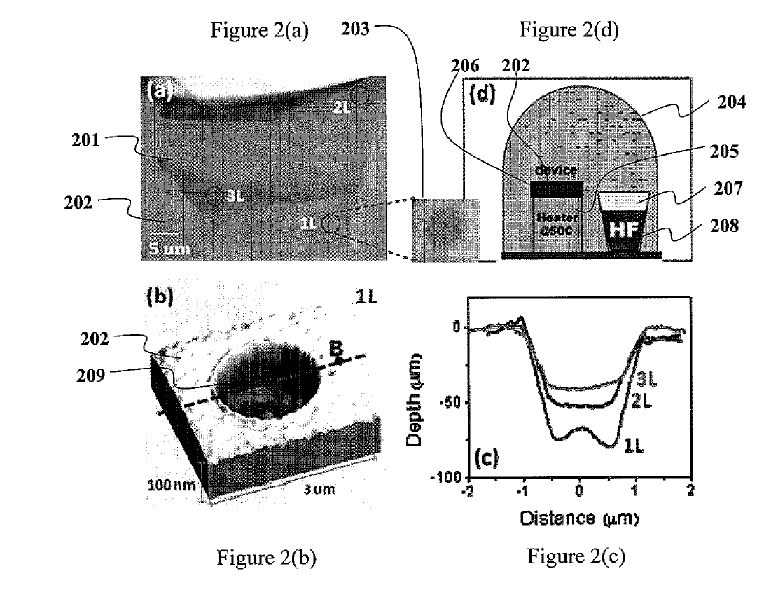

FIGS. 2(a)-(c) illustrate a silicon dioxide substrate surface fabricated in accordance with an exemplary method 100. FIG. 2(a) is an image of a multilayer graphene flake 201, deposited 130 on to a SiO₂ substrate surface 202, from which graphene layers, 1L, 2L and 3L, were patterned 140 into circular shapes using oxygen plasma etching (e.g., for 6 seconds at 50 W and 200 milliTorr (mT)). Graphene layer 1L, as illustrated in FIG. 2(a), is a single layer (a monolayer) of graphene, graphene layer 2L is a double layer, and graphene layer 3L is a triple layer. FIG. 2(a) further illustrates, in the inset 203, a magnified image of layer 1L. FIG. 2(b) is an atomic force microscope (AFM) image of the substrate 202 in FIG. 2(a) after exposure 170 to hydrofluoric acid, showing the etched cavity 209 centered at point A, where the graphene layer was located. As illustrated in FIG. 2(b), the area under the graphene layer centered on point A was etched significantly more than the surrounding areas, such as at point B, which were not covered with a layer of graphene. FIG. 2(c) illustrates the cross-sectional depth of the removed silicon dioxide 202 at each of the sites 1L, 2L and 3L. As illustrated in FIGS. 2(b) and 2(c), exposure 170 to the hydrofluoric acid remove more of the silicon dioxide substrate surface 202 underneath the graphene than in the surrounding areas of the surface. Further illustrated in FIG. 2(c), the depth of etching under single layer graphene 1L was larger than under double layer 2L, which itself was deeper than the etch under triple layer 3L. Such exemplary results are consistent with the theory that hydrofluoric acid diffuses very fast across the SiO₂-graphene interface and then etches down at a normal rate, e.g., the rate it would etch SiO₂ without the presence of graphene. As a result, etching 170 proceeds as if it were catalyzed by graphene.

FIG. 2(d) illustrates an exemplary vapor etching chamber 204 containing a heating element 205 for receiving a substrate 206 having a surface 202 and a container 207 for holding an etchant 208, e.g., hydrofluoric acid. In one exemplary embodiment, heating element 205 heats the substrate surface to 50-60° C. and the substrate surface 202 is composed of silicon dioxide having at least one graphene layer deposited thereon.

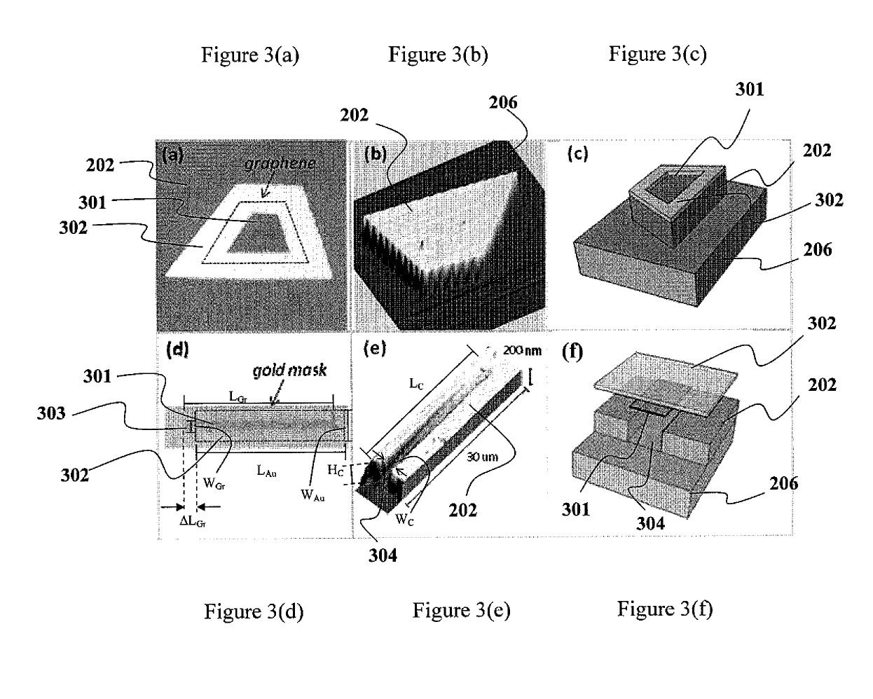

FIG. 3(a) illustrates a silicon dioxide substrate surface 202 that has a layer of graphene 301 deposited 130 onto it followed by a layer of gold 302 deposited 150 on the graphene layer such that the gold layer 302 covers the entire edge of the graphene layer 301 but leaves the central portion of the graphene 301 exposed. FIG. 3(b) is an AFM image of the silicon dioxide surface 202 of FIG. 3(a) after exposure 170 to an etchant, e.g., hydrofluoric acid. As shown in FIG. 3(b), the hydrofluoric acid etched away the silicon dioxide surrounding the gold layer 302 but did not etch the silicon dioxide underneath the gold layer 302 or the exposed graphene 301. Thus, the hydrofluoric acid does not permeate the graphene layer 301. FIG. 3(c) is an illustration of the etched substrate surface 202 of FIG. 3(b) showing the graphene layer 301 with the overlaying gold masking layer 302, all located on the substrate base 206.

FIG. 3(d) illustrates a silicon dioxide substrate surface 202 that has a layer of graphene 301 deposited 130 onto it followed by a layer of gold 302 deposited 150 on the graphene layer 301 such that the gold layer 302 cover almost all of the graphene layer 301, except a portion 303, having length ΔL_{Gr}, which can be, e.g., 1-50 μm and in some embodiments 1-30 μm, and further is less than length L_{Gr}. The graphene layer 301 has a length L_{Gr}, which can be, e.g., 1-50 μm and in some embodiments 1-30 μm, and a width W_{Gr}, which can be, e.g., 1-50 μm and in some embodiments 1-30 μm, and in one embodiment is less than length L_{Gr}. The gold layer 302 has a length L_{Au}, which can be, e.g., 1-50 μm and in some embodiments 1-30 μm and is either shorter than length L_{Gr}, by at least ΔL_{Gr}, or is deposited 150 offset by length of at least ΔL_{Gr}, and has a width W_{Au}, which can be, e.g., 1-50 μm and in some embodiments 1-30 μm and in the same or another embodiment is wider than graphene width W_{Gr} such that both edges along length of the graphene layer 301 are covered by the gold layer 302.

FIG. 3(e) is an AFM image of the silicon dioxide surface 202 of FIG. 3(d) after exposure 170 to an etchant, e.g., hydrofluoric acid. As shown in FIG. 3(e), the hydrofluoric acid etched away the silicon dioxide 202 surrounding the gold layer 302 as well as the silicon dioxide 202 underneath the graphene layer 301. Further, FIG. 3(e) illustrates that the hydrofluoric acid etches 170 for approximately the length of the graphene layer that was covered by the gold layer, forming a sloped channel 304 having depth H_{C}, e.g., 200 nm deep at the entry point A and sloping up to the original surface of the silicon dioxide 202, length L_{C}, e.g., approximately 30 μm long and width W_{C}, e.g., 2 μm wide. FIG. 3(f) is an illustration of the configuration of FIG. 3(e), showing the gold capping layer 302 on top of the graphene layer 301 and the channel 304 that was etched 170 out from underneath the graphene 301. Further, FIG. 3(f) is also an illustration of a graphene fabricated device 305 having a channel 304 etched 170 into the silicon dioxide substrate surface 202 beneath a layer of graphene 301. The graphene fabricated device 305 in FIG. 3(f) further includes a layer of metal 302, e.g., gold, covering substantially all of the layer of graphene 301, but leaving a portion 303 (as shown in FIG. 3(d)) exposed.

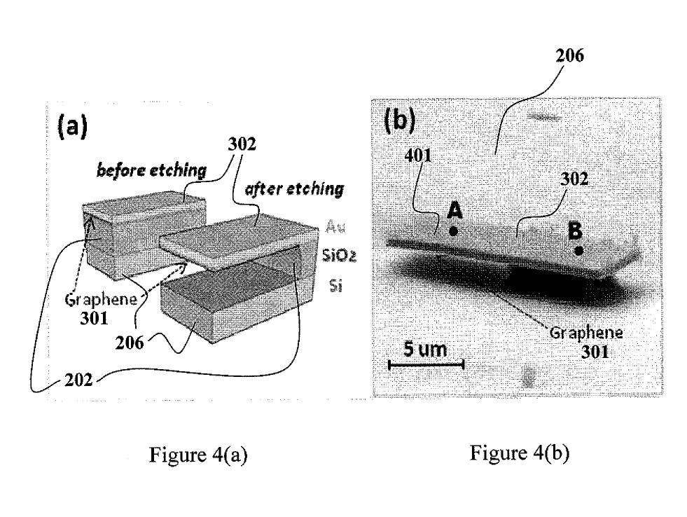

FIG. 4(a) illustrates a silicon dioxide substrate surface 202 having a graphene layer and gold layer deposited 130, 150 before and after etching 170. FIG. 4(b) is a scanning electron microscope (SEM) image of a silicon substrate 206 prepared in the manner illustrated in FIG. 4(a). As shown in FIG. 4(b), etching 170 of the silicon dioxide substrate surface removes a portion of the SiO₂ beneath the graphene 301 and gold layers 302, forming a suspended device 401 on the base silicon substrate 206. FIGS. 4(a)-(b) further illustrate a graphene fabricated device 401 which includes at least one layer of graphene 301 suspended above a silicon substrate 206. As illustrated in FIG. 4(a), the suspended graphene fabricated device 401 can further include at least one layer of metal 302, e.g., gold, deposited on the graphene 301.

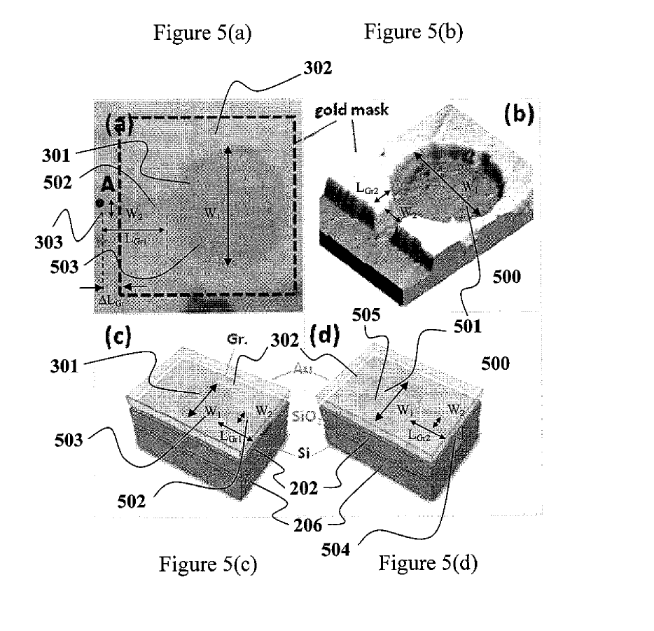

FIG. 5(a) illustrates a silicon dioxide substrate surface 202 having a gold layer 302 deposited 150 on top of a layer of graphene 301 deposited 130 on the SiO₂ surface 202. In this example the graphene layer 301 has been patterned 140 into a circular shape having a tail ending with an exposed portion 303 ending at point A, which is not covered by the gold layer 302, as illustrated in FIG. 5(a). As illustrated in FIG. 5(a), the layer of graphene can be patterned 140 such that it has a first portion 502, having a first width W₁, e.g., 1-50 μm and in some embodiments 1-30 μm, and length L_{Gr1}, e.g., 1-50 μm and in some embodiments 1-30 μm, and it has a second portion 503, having a second width W₂, e.g., 1-50 μm and in some embodiments 1-30 μm. The first portion 502 extends from underneath the metal layer 302 to include exposed portion 303, which extends from under the metal layer 302 by length ΔL_{Gr}, which can be, e.g., 1-50 μm and in some embodiments 1-30 μm. In one exemplary embodiment, the first width W₁ of the first portion 502, and correspondingly the width W₁ of the exposed portion 303, is smaller than the width W₂ of the second portion (e.g., the covered portion) 503.

Exposed portion 303 has a length ΔL_{Gr}, which can be, e.g., 1-50 μm and in some embodiments 1-30 μm. After etching 170 the SiO₂ surface 202, the resulting silicon dioxide substrate surface 202 appears as illustrated in FIG. 5(b), which is a AFM image of the substrate 202 after etching 170 and removal 180, 190 of the graphene and gold layers. FIGS. 5(c)-(d) are 3D renderings of the processes illustrated in FIGS. 5(a)-(b), with FIG. 5(c) illustrating the layers of graphene 301 and gold 302 deposited 130, 150 on the SiO₂ surface 202 and FIG. 5(d) illustrates the same configuration after etching 170, showing the removal of a cavity 501 of SiO₂ beneath the graphene and gold layers 301, 302.

FIGS. 5(b) and 5(d) further illustrates a graphene fabricated device 500 which includes a cavity 501 etched into the substrate surface 202 beneath at least one flake of graphene. As illustrated in FIG. 5(d), the cavity 501 can include a first portion 504, having a first width W₁, e.g. 1-50 μm and in some embodiments 1-30 μm, and length L_{Gr2}, e.g., 1-50 μm and in some embodiments 1-30 μm, and it has a second portion 505, having a second width W₂, e.g., 1-50 μm and in some embodiments 1-30 μm. In one embodiment the length L_{Gr2} of the first portion 504 can be (L_{Gr1}−ΔL_{Gr}), e.g., the length of the first portion 502 of the graphene layer 301 minus the length ΔL_{Gr}, of the exposed portion 303. As illustrated in FIG. 5(d), the graphene fabricated device 500 can further include at least one layer of metal 302, e.g., gold, deposited 150 on the layer of graphene 301, such that substantially all of the graphene layer 301 is covered except for at least one edge of the first portion that is left exposed. In addition, though not illustrated in FIG. 5(d), the graphene layer 301 can remain in place, e.g., suspended, from the layer of metal 302 after exposure 170 to an etchant.

It will be understood that the foregoing is only illustrative of the principles described herein, and that various modifications can be made by those skilled in the art without departing from the scope and spirit of the disclosed subject matter. For example, the methods described herein are used for etching silicon dioxide. It is understood that that techniques described herein are useful for other materials that can be etched utilizing graphene. Moreover, features of embodiments described herein can be combined and/or rearranged to create new embodiments.

We claim:

1. A method for fabricating an etched surface on a substrate comprising:
depositing at least one layer of graphene on the surface on the substrate;
patterning the deposited at least one layer of graphene; and
exposing the surface on the substrate to an acid to etch the surface on the substrate.

2. The method of claim 1, further comprising forming the at least one layer of graphene from graphite.

3. The method of claim 2, wherein forming the at least one layer of graphene comprises mechanically exfoliating the layer of graphene from the graphite.

4. The method of claim 2, wherein forming the at least one layer of graphene comprises chemically exfoliating the graphene from the graphite.

5. The method of claim 2, wherein forming the at least one layer of graphene comprises utilizing vapor deposition to form the layer of graphene from the graphite.

6. The method of claim 1, further comprising depositing at least one layer of metal on top of the deposited at least one layer of graphene, wherein the at least one layer of metal leaves at least one portion of an edge of the at least one layer of graphene exposed.

7. The method of claim 1, wherein the surface on the substrate comprises silicon dioxide.

8. The method of claim 1, wherein the acid comprises hydrofluoric acid.

9. The method of claim 6, wherein the layer of metal comprises a layer of gold.

10. The method of claim 1, wherein patterning the deposited at least one layer of graphene comprises utilizing lithography to pattern the deposited at least one layer of graphene.

11. The method of claim 1, wherein patterning the deposited at least one layer of graphene comprises oxygen plasma etching to pattern the deposited at least one layer of graphene.

12. The method of claim 1, wherein exposing the surface on the substrate to an acid comprises acid vapor phase etching the surface on the substrate.

13. The method of claim 1, wherein exposing the surface on the substrate to an acid comprises exposing the surface on the substrate to a buffered oxide etchant.

14. A graphene fabricated device comprising at least one layer of graphene partially suspended above a substrate.

15. The graphene fabricated device of claim 14, further comprising at least one layer of metal deposited on the at least one layer of graphene

16. The graphene fabricated device of claim 15, wherein the at least one layer of metal comprises gold.

17. A graphene fabricated device comprising at least one channel etched into a surface on a substrate beneath at least one flake of graphene.

18. The graphene fabricated device of claim 17, further comprising at least one layer of metal deposited on the at least one layer of graphene, wherein the at least one layer of metal substantially covers the at least one layer of graphene leaving at least one portion of an edge of the at least one layer of graphene exposed.

19. The graphene fabricated device of claim 17, where the at least one channel comprises a nanoscale channel.

20. A graphene fabricated device comprising at least one cavity etched into a surface on a substrate beneath at least one flake of graphene.

21. The graphene fabricated device of claim 20, further comprising at least one layer of metal deposited on the at least one layer of graphene,
wherein the at least one layer of metal substantially covers the at least one layer of graphene leaving at least one portion of an edge of the at least one layer of graphene exposed and covering the remainder of the at least one layer of graphene, and
wherein the exposed portion of the at least one layer of graphene has a first width and the covered portion of the at least one layer of graphene has a second width, the first width being less than the second width.
